(19) United States
(12) Patent Application Publication
(10) Pub. No.: US 2011/0036400 A1
(43) Pub. Date: Feb. 17, 2011

(54) BARRIER LAYER

(75) Inventors: Stephen P. Murphy, Perrysburg, OH (US); Kevin V. Crots, Perrysburg, OH (US)

Correspondence Address: STEPTOE & JOHNSON LLP, 1330 CONNECTICUT AVENUE, N.W., WASHINGTON, DC, 20036, US

(73) Assignee: First Solar, Inc., Perrysburg, OH (US)

(21) Appl. No.: 12/858,147

(22) Filed: Aug. 17, 2010

Related U.S. Application Data
(60) Provisional application No. 61/234,501, filed on Aug. 17, 2009.

(51) Int. Cl. H01L 31/0203; H01L 31/18; H01L 23/28

(52) U.S. Cl. 136/256; 438/64; 257/787; 257/E31.118; 257/E21.502; 257/E23.116

(57) ABSTRACT

A method for manufacturing a photovoltaic module may include coating a portion of a substrate with a coating material; depositing a barrier material layer on a least a portion of an edge of the substrate; and curing the barrier material layer, where the barrier material layer is effective as a barrier to the coating material.

### CLAIM FOR PRIORITY

This application claims priority under 35 U.S.C. §119(e) to U.S. Provisional Patent Application Ser. No. 61/234,501 filed on Aug. 17, 2009, which is hereby incorporated by reference.

### TECHNICAL FIELD

The present invention relates to photovoltaic modules and methods of production.

### BACKGROUND

Photovoltaic modules can include semiconductor material deposited over a substrate, for example, with a first layer serving as a window layer and a second layer serving as an absorber layer. The semiconductor window layer can allow the penetration of solar radiation to the absorber layer, such as a cadmium telluride layer, which converts solar energy to electricity. Photovoltaic modules can also contain one or more transparent conductive oxide layers, which are also often conductors of electrical charge.

### DESCRIPTION OF DRAWINGS

FIG. 1 is a schematic of a photovoltaic module.

FIG. 2 is a schematic of a photovoltaic module.

FIG. 3 is a schematic of a photovoltaic module.

FIG. 4 is a schematic of a photovoltaic module.

### DETAILED DESCRIPTION

A photovoltaic module can include a transparent conductive oxide layer adjacent to a substrate and layers of semiconductor material. The transparent conductive oxide can include a zinc oxide or a tin oxide, which can be a doped, binary, ternary or quaternary material. The layers of semiconductor material can include a bi-layer, which may include an n-type semiconductor window layer, and a p-type semiconductor absorber layer. The n-type window layer and the p-type absorber layer may be positioned in contact with one another to create an electric field. Photons can free electron-hole pairs upon making contact with the n-type window layer, sending electrons to the n side and holes to the p side. Electrons can flow back to the p side via an external current path. The resulting electron flow provides current, which combined with the resulting voltage from the electric field, creates power. The result is the conversion of photon energy into electric power. To preserve and enhance device performance, numerous layers can be positioned above the substrate in addition to the semiconductor window and absorber layers.

Photovoltaic modules can be formed on optically transparent substrates, such as glass. Because glass is not conductive, a transparent conductive oxide (TCO) layer is typically deposited between the substrate and the semiconductor bi-layer. A smooth buffer layer can be deposited between the TCO layer and the semiconductor window layer to decrease the likelihood of irregularities occurring during the formation of the semiconductor window layer. Additionally, a barrier layer can be incorporated between the substrate and the TCO layer to lessen diffusion of sodium or other contaminants from the substrate to the semiconductor layers, which could result in degradation and delamination. The barrier layer can be transparent, thermally stable, with a reduced number of pin holes and having high sodium-blocking capability, and good adhesive properties. Therefore the TCO can be part of a three-layer stack, which may include, for example, a silicon dioxide barrier layer, a TCO layer, and a buffer layer (e.g., a tin (IV) oxide). The buffer layer can include various suitable materials, including tin oxide, zinc tin oxide, zinc oxide, and zinc magnesium oxide. A photovoltaic module can include a cadmium sulfide window layer deposited over a TCO stack and a cadmium telluride absorber layer deposited over the cadmium sulfide layer. Cadmium telluride photovoltaic modules offer several advantages over other photovoltaic technologies. Among those are superior light absorption properties under cloudy and diffuse light conditions and ease of manufacturing.

A barrier material layer may be incorporated into the photovoltaic module along an edge of a first substrate. The barrier material layer should have strong adhesive qualities, and exhibit resistance to ultraviolet light, moisture, abrasion, and extreme variance in temperature. The material should also be durable, and contain a coefficient of expansion that is as close to glass as possible. The barrier material layer can act as an edge-encapsulation seal to encapsulate one or more layers of coating within the photovoltaic module. For example, the barrier material layer can provide a barrier for one or more semiconductor layers in the photovoltaic module. The barrier material layer may also help confine any other coating material to the surface of a substrate. The barrier material layer may also be effective as a barrier to water or air contacting one or more layers of coating within the photovoltaic module.

In one aspect, a method for manufacturing a photovoltaic module may include coating a portion of a substrate with a coating material. The method may include depositing a barrier material layer on a least a portion of an edge of the substrate. The method may include curing the barrier material layer. The barrier material layer may be effective as a barrier to the coating material.

The barrier material layer may include an epoxy, an acrylic photopolymer, a conformal coating, or any combination thereof. The barrier material layer may include a silicon-containing material, for example, a silicone. The depositing may include spraying a thin coating. The depositing may include moving a liquid through a needle toward the substrate. The depositing may include moving a liquid through a fountain-like outlet toward the substrate. The depositing may include brushing a liquid on the substrate. The depositing may include depositing the barrier material layer proximate to an interlayer. The depositing may include depositing the barrier material layer proximate to the coating material. The curing may include curing at about room temperature for about 3 to about 25 hours. The curing may include curing at about room temperature for about 8 to about 20 hours. The curing may include forming an edge-encapsulation seal. The curing may include applying an ultraviolet light. The curing may include heating. The heating may include IR heating. The heating may include resistive heating. The curing may include heating an epoxy. The curing may include applying an ultraviolet light to an acrylic photopolymer. The curing may include applying an ultraviolet light to an epoxy. The curing may include applying an ultraviolet light to a conformal coating including a photopolymer.

In one aspect, a photovoltaic module may include a substrate coated with a coating material. The substrate may include an edge. The photovoltaic module may include a barrier material layer contacting at least a portion of the edge of the substrate. The barrier material layer may include a barrier to the coating material.

The photovoltaic module may include an interlayer material on the substrate and proximate to the coating material. The barrier material layer may include an edge-encapsulation seal. The viscosity of the barrier material has a viscosity suitable for applying a coating on a substrate prior to curing to form a solid. The barrier material layer may include an epoxy. The epoxy may have a viscosity of about 1000 to about 10000 cP, about 1500 to about 9000 cP, about 4000 to about 6000 cP or about 5000 to about 5500 cP. The barrier material layer may include an acrylic photopolymer. The acrylic photopolymer may have a viscosity of about 10 to about 25 cP or about 15 to about 20 cP. The acrylic photopolymer may have a viscosity of about 200 to about 800 cP or about 350 to about 600 cP. The barrier material layer may include a conformal coating. The conformal coating may have a viscosity of about 50 to about 250 cP. The conformal coating may have a viscosity of about 100 to about 150 cP. The barrier material layer may include a silicon-containing material, for example, a silicone. The barrier material layer may physically contact at least a portion of the interlayer material. The substrate may include a glass. The coating material may include a transparent conductive oxide layer. The barrier material layer may contact at least a portion of an edge of the transparent conductive oxide layer. The coating material may include a cadmium sulfide layer on the transparent conductive oxide layer, and a cadmium telluride layer on the cadmium sulfide layer. The barrier material layer may be effective as a barrier to air or water contacting the coating material.

In one aspect, a photovoltaic module may include a substrate. The photovoltaic module may include a transparent conductive oxide layer on the substrate. The photovoltaic module may include a barrier material layer contacting at least a portion of an edge of the substrate. The barrier material layer may include a barrier to the transparent conductive oxide layer. The barrier material layer may include an epoxy, an acrylic photopolymer, or a conformal coating. The barrier material layer may include a silicon-containing material, for example, a silicone. The barrier material layer may include an edge-encapsulation seal.

In one aspect, a substrate may include a coating material and a barrier material layer contacting at least a portion of an edge of the substrate. The barrier material layer may include a barrier to the coating material. The barrier material layer may include an epoxy, an acrylic photopolymer, or a conformal coating. The barrier material layer may include a silicon-containing material, for example, a silicone. The barrier material layer may include an edge-encapsulation seal.

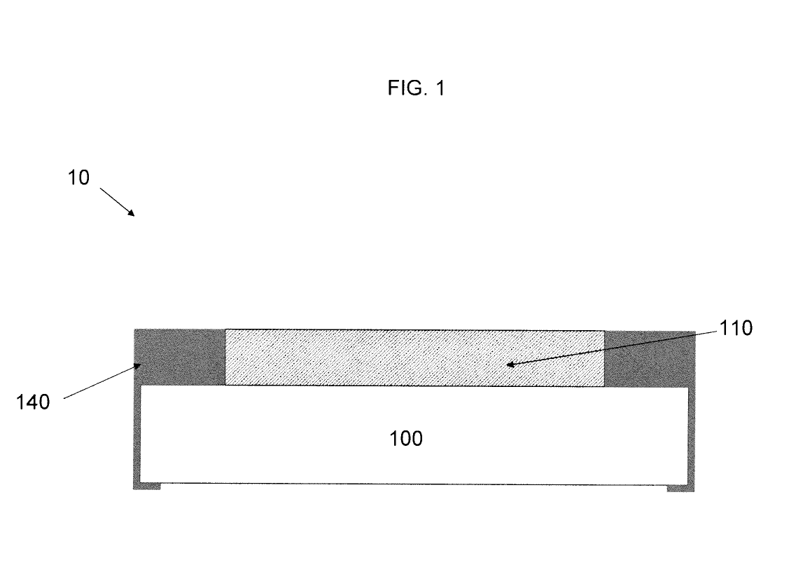

Referring to FIG. 1, a photovoltaic module 10 can include a substrate 100 with a barrier material layer 140 deposited thereon. Barrier material layer 140 can be deposited on an edge of substrate 100, and may contact one or more coatings within photovoltaic module 10. For example, barrier material layer 140 can contact a portion of an edge of a transparent conductive oxide layer 110. Substrate 100 may include any suitable material, including a glass, for example, a soda-lime glass. Transparent conductive layer 110 can include any suitable transparent conductive oxide. Barrier material layer 140 can provide a barrier for transparent conductive oxide layer 110, and confine it to the surface of substrate 100. Transparent conductive oxide layer 110 may be part of a transparent conductive oxide stack. One or more device layers may be deposited on transparent conductive oxide layer 110 (which may or may not be part of a transparent conductive oxide stack), including, for example, a cadmium telluride layer on a cadmium sulfide layer.

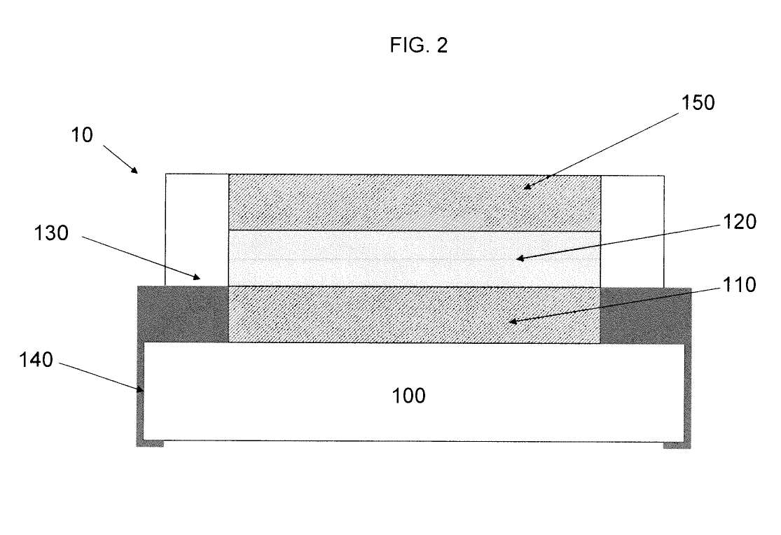

Referring to FIG. 2, by way of example, device layer 120 can be deposited on transparent conductive oxide layer 110, which may be a part of a transparent conductive oxide stack. Device layer 120 can include any suitable semiconductor material, including, for example, a cadmium telluride layer on a cadmium sulfide layer. A contact metal 150 can be deposited thereon to serve as a back contact for photovoltaic module 10. An interlayer 130 can be deposited adjacent to substrate 100. Interlayer 130 can contact barrier material layer 140. For example, interlayer 130 can be deposited on barrier material layer 140. Interlayer 130 may include any suitable material, including a thermoplastic. For example, interlayer 130 may include acrylonitrile butadiene styrene (ABS), acrylic (PMMA), celluloid, cellulose acetate, cycloolefin copolymer (COC), ethylene-vinyl acetate (EVA), ethylene vinyl alcohol (EVOH), fluoroplasics (PTFE), ionomers, Kydex®, liquid crystal polymer (LCP), polyacetal (POM), polyacrylates, polyacrylonitrile (PAN), polyamide (PA), polyamide-imide (PAI), polyaryletherketone (PAEK), polybutadiene (PBD), polybutylene (PB), polybutylene terephthalate (PBT), polycaprolactone (PCL), polychlorotrifluoroethylene (PCTFE), polyethylene terephthalate (PET), polycyclohexylene dimethylene terephthalate (PCT), polycarbonate (PC), polyhydroxyalkanoates (PHAs), polyketone (PK), polyester, polyethylene (PE), polyetheretherketone (PEEK), polyetherketoneketone (PEKK), polyetherimide (PEI), polyethersulfone (PES), polyethylenechlorinates (PEC), polyimide (PI), polyactic acid (PLA), polymethylpentene (PMP), polyphenylene oxide (PPO), polyphenylene sulfide (PPS), polyphthalamide (PPA), polypropylene (PP), polystyrene (PS), polysulfone (PSU), polytrimethylene terephthalate (PTT), polyurethane (PU), polyvinyl acetate (PVA), polyvinyl chloride (PVC), polyvinylidene chloride (PVDC), styrene-acrylonitrile (SAN), butyl rubber, or any combination thereof.

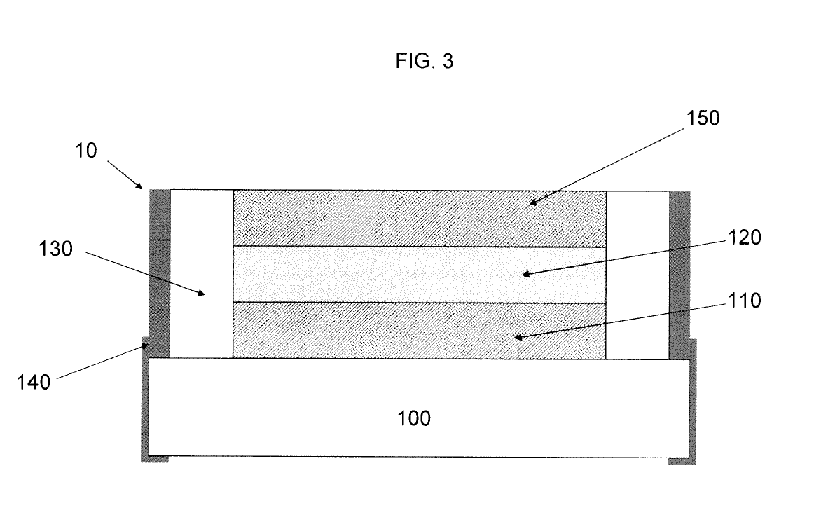

Interlayer 130 may also be deposited directly on substrate 100 adjacent to one or more coating layers, with barrier material layer 140 deposited thereafter. Referring to FIG. 3, by way of example, interlayer 130 may be deposited on the edge of substrate 100, adjacent to transparent conductive layer 110 and device layer 120. The edge of substrate 100 may have one or more layers of coating removed by laser ablation, or any other means, prior to deposition of interlayer 130. As shown in FIGS. 1-3, barrier material layer 140 can be deposited on the edge of substrate 100. Barrier material layer 140 may physically contact any portion of an edge of substrate 100. For example, barrier material layer 140 may touch a bottom portion of substrate 100, the side of substrate 100, or a top edge of substrate 100. Barrier material layer 100 may also physically contact one or more portions of interlayer 130, as shown in FIGS. 2 and 3. Barrier material layer 140 may also physically contact one or more coating layers on substrate 100, such as one or both of transparent conductive layer 110 and device layer 120.

A variety of materials may be used for barrier material layer 140. Barrier material layer 140 may contain any suitable epoxy or acrylic, as well as any conformal coating. Barrier material layer may also include any suitable silicon-containing material, including, for example, a silicone. Barrier material layer 140 may be deposited using any suitable technique. For example, barrier material layer 140 may be sprayed onto an edge of substrate 100 as a thin coating. Barrier material layer 140 may be deposited as a liquid via a small outlet, such as a needle, to ensure precision and accuracy. Alternatively, barrier material layer may be deposited from a large outlet, such as a fountain, to ensure greater speed of application. Barrier material layer 140 may also be deposited via one or more brushes.

Barrier material layer 140 may have any suitable viscosity. For example, barrier material layer 140 may have a viscosity in a range of about 5 to about 8000 cP. For example, barrier material layer 140 may include an epoxy with a viscosity of about 4000 to about 6000 cP, for example, about 5300 cP. Barrier material layer 140 may also include an acrylic photopolymer having a viscosity of about 200 to about 800 cP, for example, about 350 to about 600 cP. Alternatively, the acrylic photopolymer could have a viscosity of about 10 to about 30 cP, for example, about 15 to about 20 cP. Barrier material layer 140 may also include a conformal coating with viscosity of about 100 to about 200 cP, for example, about 125 cP.

Barrier material layer 140 may have any suitable level of hardness or durability. For example, barrier material layer 140 may have a durability of about 30 to about 80 Shore A. For example, barrier material layer 140 may include an acrylic photopolymer having a durability of about 75 to about 80 Shore A, or about 35 to about 45 Shore A. Barrier material layer 140 may also include a conformal coating having a durability of about 70 to about 80 Shore A.

Following deposition, barrier material layer 140 may be cured using any suitable technique. For example, barrier material layer 140 may be cured at room temperature for about 3 to about 25 hours, about 4 to about 24 hours, or about 8 to about 20 hours. Barrier material layer 140 may also be cured using an ultraviolet light. The ultraviolet light can be applied for any suitable duration, including for about 1 second to about 2 minutes, for example, about 30 seconds. The ultraviolet light can be applied using any suitable level of power, including about 30 mW/cm² to about 300 mW/cm², for example, about 100 mW/cm². The ultraviolet light may also consist of any suitable wavelength, for example, about 10 to about 400 nm. For example, an ultraviolet light may be applied to an acrylic photopolymer at about 100 mW/cm² for less than about 30 seconds at about 365 nm. Alternatively, an ultraviolet light can be applied to the acrylic photopolymer at about 3.5 J/cm² at about 315 to about 395 nm. An ultraviolet light can be applied to a conformal coating at about 50 mW/cm² for about 3 seconds. Barrier material layer 140 may also be cured using a variety of heating techniques. Barrier material layer 140 may be heated at any suitable temperature, including about 100 to about 30° C., for example, about 120 to about 15° C. Barrier material layer 140 may also be heated for any suitable duration, including from about 30 seconds to about 10 minutes. For example, barrier material layer 140 may be heated, either resistively or through infrared, at about 10° C. to about 20° C. for any suitable duration, including about 30 seconds to about 10 minutes. The curing may include multiple steps. For example, an epoxy may be heated at about 15° C. for about 1 minute, and then at about 12° C. for about 5 minutes.

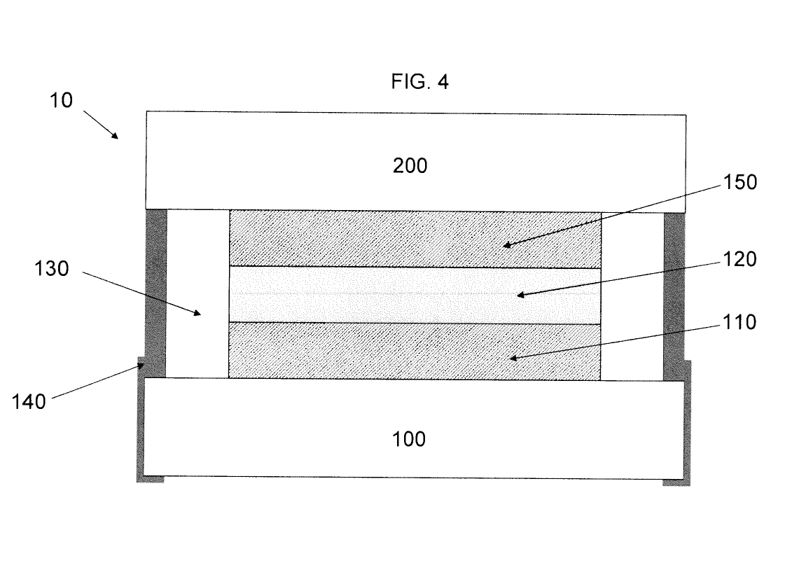

Referring to FIG. 4, following deposition of barrier material layer 140, a back support 200 may be deposited onto contact metal 150. Back support 200 can include any suitable material, including a glass, for example, a soda-lime glass.

The embodiments described above are offered by way of illustration and example. It should be understood that the examples provided above may be altered in certain respects and still remain within the scope of the claims. It should be appreciated that, while the invention has been described with reference to the above preferred embodiments, other embodiments are within the scope of the claims.

What is claimed is:

1. A method for manufacturing a photovoltaic module, the method comprising:
coating a portion of a substrate with a coating material;
depositing a barrier material layer on a least a portion of an edge of the substrate; and
curing the barrier material layer, wherein the barrier material layer is effective as a barrier to the coating material.

2. The method of claim 1, wherein the barrier material layer comprises an epoxy, an acrylic photopolymer, a conformal coating, a silicon-containing material, or a silicone.

3. The method of claim 1, wherein the depositing comprises:
spraying a thin coating;
moving a liquid through a needle toward the substrate;
moving a liquid through a fountain-like outlet toward the substrate;
brushing a liquid on the substrate;
depositing the barrier material layer proximate to an interlayer; or
depositing the barrier material layer proximate to the coating material.

4. The method of claim 1, wherein the curing comprises:
curing at about room temperature for about 3 to about 25 hours;
forming an edge-encapsulation seal;
applying an ultraviolet light; or
heating.

5. The method of claim 4, wherein the heating comprises IR heating or resistive heating.

6. The method of claim 1, wherein the curing comprises:
curing an epoxy;
applying an ultraviolet light to an acrylic photopolymer;
applying an ultraviolet light to an epoxy; or
applying an ultraviolet light to a conformal coating including a photopolymer.

7. A photovoltaic module comprising:
a substrate coated with a coating material, wherein the substrate comprises an edge; and
a barrier material layer contacting at least a portion of the edge of the substrate, wherein the barrier material layer comprises a barrier to the coating material.

8. The photovoltaic module of claim 7, further comprising an interlayer material on the substrate and proximate to the coating material.

9. The photovoltaic module of claim 7, wherein the barrier material layer comprises an edge-encapsulation seal, an epoxy, an acrylic photopolymer, a conformal coating, a silicon-containing material, or a silicone.

10. The photovoltaic module of claim 9, wherein:
the epoxy has a viscosity of about 1000 to about 10000 cP;
the acrylic photopolymer has a viscosity of about 10 to about 25 cP, or about 200 to about 800 cP; or
the conformal coating has a viscosity of about 50 to about 250 cP.

11. The photovoltaic module of claim 7, wherein the barrier material layer physically contacts at least a portion of the interlayer material.

12. The photovoltaic module of claim 7, wherein the substrate comprises a glass.

13. The photovoltaic module of claim 12, wherein the coating material comprises a transparent conductive oxide layer.

14. The photovoltaic module of claim 13, wherein the barrier material layer contacts at least a portion of an edge of the transparent conductive oxide layer.

15. The photovoltaic module of claim 13, wherein the coating material further comprises a cadmium sulfide layer on the transparent conductive oxide layer, and a cadmium telluride layer on the cadmium sulfide layer.

16. The photovoltaic module of claim 7, wherein the barrier material layer is effective as a barrier to air or water contacting the coating material.

17. A photovoltaic module comprising:
a substrate;
a transparent conductive oxide layer on the substrate; and
a barrier material layer contacting at least a portion of an edge of the substrate, wherein the barrier material layer comprises a barrier to the transparent conductive oxide layer.

18. The photovoltaic module of claim 17, wherein the barrier material layer comprises an epoxy, an acrylic photopolymer, a conformal coating, an edge-encapsulation seal, a silicon-containing material, or a silicone.

19. A substrate comprising:
a coating material; and
a barrier material layer contacting at least a portion of an edge of the substrate, wherein the barrier material layer comprises a barrier to the coating material.

20. The substrate of claim 19, wherein the barrier material layer comprises an epoxy, an acrylic photopolymer, a conformal coating, an edge-encapsulation seal, a silicon-containing material, or a silicone.
